(19) United States
(12) Patent Application Publication
(10) Pub. No.: US 2025/0318373 A1
(43) Pub. Date: Oct. 9, 2025

(54) DISPLAY DEVICE

(71) Applicant: Samsung Display Co., Ltd., Yongin-Si (KR)

(72) Inventor: Jong Hyun CHOI, Yongin-si (KR)

(21) Appl. No.: 18/914,320

(22) Filed: Oct. 14, 2024

(30) Foreign Application Priority Data
Apr. 5, 2024 (KR) 10-2024-0046494

(51) Int. Cl. H10K 59/131; H10K 59/122; H10K 59/126

(52) U.S. Cl. CPC H10K 59/131; H10K 59/122; H10K 59/126

(57) ABSTRACT

A display device comprises a substrate, a circuit layer, and an element layer. The circuit layer comprises a light blocking layer, a substrate buffer layer, a semiconductor layer, a first gate insulating layer, a first gate conductive layer, a second gate insulating layer, a second gate conductive layer, an interlayer insulating layer, a grid comprising first and second extension grooves, a bending groove extending through at least one of the substrate buffer layer, the first gate insulating layer, the second gate insulating layer, or the interlayer insulating layer, a main buffer portion covering the grid, and a sub-buffer portion disposed on the same layer as the main buffer portion and covering the bending groove. Each of the first extension grooves and the second extension grooves reaches a part of at least one of the substrate, the light blocking layer, the first gate conductive layer, or the second gate conductive layer.

### CROSS-REFERENCE TO RELATED APPLICATION

This application claims priority to and the benefit of Korean Patent Application No. 10-2024-0046494 filed on Apr. 5, 2024, in the Korean Intellectual Property Office under 35U.S.C. 119, the contents of which in its entirety are incorporated herein by reference.

### BACKGROUND

### 1. Technical Field

The present disclosure relates to a display device.

### 2. Description of the Related Art

As the information society advances, the demand for display devices which display image is increasing in various ways. For example, display devices are employed in various electronic devices such as smartphones, digital cameras, laptop computers, navigation devices, and smart televisions.

The display device may be a flat panel display device such as a liquid crystal display device, a field emission display device and a light-emitting display device. Examples of the light-emitting display device may include an organic light-emitting display device including organic light-emitting elements, an inorganic light-emitting display device including inorganic light-emitting elements such as inorganic semiconductors, and a micro light-emitting display device including micro light-emitting elements.

The organic light-emitting display device displays an image using light-emitting elements, each of which includes a light-emitting layer made of an organic light-emitting material. As described above, the organic light-emitting display device implements image display by using a self-light-emitting element, and thus may have relatively superior performance in power consumption, response speed, luminous efficiency, luminance, and wide viewing angle compared to other display devices.

In the display device, a display surface from which light is emitted may include a display area in which an image is displayed, and a non-display area surrounding the display area. Emission areas which emit light having respective luminance and colors may be arranged in the display area.

### SUMMARY

During the manufacturing process and use of a display device, external impact may be applied to the display device due to situations such as collision with other objects or drop of a device. If such external impact is greater than or equal to a critical level, the display device may be easily deformed or damaged, leading to a reduction in the lifespan and usability of the display device.

Additionally, when the display device is folded, bent, or rolled, the folded, bent or rolled portion may have bending stress, making them more vulnerable to external impact.

Thus, aspects of the present disclosure provide a display device having improved elasticity, which may mitigate external impacts or reduce transmission of the external impact.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a display device comprises a substrate comprising a main region and a sub-region protruding from one side of the main region, a circuit layer disposed on the substrate, and an element layer disposed on the circuit layer. The sub-region may comprise a bending area which may be transformed into a bent shape. The circuit layer may comprise a light blocking layer disposed on the substrate, a substrate buffer layer covering the light blocking layer, a semiconductor layer disposed on the substrate buffer layer, a first gate insulating layer covering the semiconductor layer, a first gate conductive layer disposed on the first gate insulating layer, a second gate insulating layer covering the first gate conductive layer, a second gate conductive layer disposed on the second gate insulating layer, an interlayer insulating layer covering the second gate conductive layer, a grid formed in at least a part of the main region and comprising first and second extension grooves which intersect each other, a bending groove formed in the bending area and extending through at least one of the substrate buffer layer, the first gate insulating layer, the second gate insulating layer, or the interlayer insulating layer, a main buffer portion disposed in the main region and covering the grid, and a sub-buffer portion covering the bending groove and disposed in the sub-region, wherein the sub-buffer portion may be disposed on a same layer as the main buffer portion. Each of the first extension grooves and the second extension grooves may reach a part of at least one of the substrate, the light blocking layer, the first gate conductive layer, or the second gate conductive layer. Each of the substrate buffer layer, the first gate insulating layer, the second gate insulating layer, the interlayer insulating layer, the main buffer portion, and the sub-buffer portion may contain an inorganic insulating material.

The main region may comprise a display area in which emission areas are arranged, and a non-display area disposed around the display area. The sub-region may further comprise a first sub-region disposed between the main region and a first side of the bending area, and a second sub-region connected to a second side of the bending area, and the grid may be formed in at least the display area of the main region.

The circuit layer may further comprise a grid filling layer disposed on the main buffer portion, filling the grid, and containing an organic insulating material.

The circuit layer may further comprise a buffer separation groove formed in the bending area and extending through the sub-buffer portion. The buffer separation groove may extend in a first direction crossing a second direction along which the first sub-region and the second sub-region face each other. A portion of the sub-buffer portion adjacent to the first sub-region may be spaced apart from another portion of the sub-buffer portion adjacent to the second sub-region by the buffer separation groove.

The display device may further comprise two or more concave grooves formed in the bending area, and one or more convex portions disposed between the two or more concave grooves. Each of the two or more concave grooves may extend through a part of the substrate and extend in a first direction crossing a second direction along which the first sub-region and the second sub-region face each other. The two or more concave grooves and the one or more convex portions may be arranged alternately along the second direction. A portion of the substrate overlapping the bending groove may have a surface with a concavo-convex structure formed by the two or more concave grooves and the one or more convex portions. The sub-buffer portion may cover the portion of the substrate having the surface with the concavo-convex structure.

A depth of each of the two or more concave grooves may be less than a thickness of the substrate.

A thickness of a first portion of the sub-buffer portion disposed on the one or more convex portions may be a first thickness. A thickness of a second portion of the sub-buffer portion disposed on a side surface of each of the two or more concave grooves may be a second thickness less than or equal to the first thickness.

An inclination of the side surface of each of the two or more concave grooves with respect to a bottom surface of each of the two or more concave grooves may be less than or equal to 90 degrees.

The display device may further comprise one or more mask layers disposed on the one or more convex portions. The sub-buffer portion may cover the one or more mask layers.

An inclination of the side surface of each of the two or more concave grooves with respect to the bottom surface of each of the two or more grooves may be less than 90 degrees.

A width of the one or more mask layers may be greater than a width of the one or more convex portions. An edge of the one or more mask layers may protrude beyond the two or more concave grooves.

The one or more mask layers may be disposed on a same layer as the light blocking layer.

The display device may further comprise a bank covering the bending groove and comprising two or more bank layers stacked on each other. Each of the two or more bank layers may contain an organic insulating material. The bank may be in contact with the sub-buffer portion or the substrate.

The circuit layer may further comprise a first source-drain conductive layer disposed on the interlayer insulating layer, a first planarization layer covering the first source-drain conductive layer and the grid, a second source-drain conductive layer disposed on the first planarization layer, and a second planarization layer covering the second source-drain conductive layer. The element layer may comprise anode electrodes disposed in the emission areas, a pixel defining layer disposed in a non-emission area between the emission areas and covering an edge of each of the anode electrodes, a spacer layer disposed on a part of the pixel defining layer, light emitting layers disposed on the anode electrodes, and a cathode electrode disposed on the pixel defining layer, the spacer layer, and the light emitting layers. The two or more bank layers may comprise a first bank layer disposed on a same layer as the first planarization layer, a second bank layer disposed on a same layer as the second planarization layer, a third bank layer disposed on a same layer as the pixel defining layer, and a fourth bank layer disposed on a same layer as the spacer layer.

According to an embodiment of the present disclosure, a display device comprises a substrate comprising a main region and a sub-region protruding from one side of the main region, a circuit layer disposed on the substrate, and an element layer disposed on the circuit layer. The sub-region may comprise a bending area which is transformed into a bent shape, a first sub-region disposed between the main region and a first side of the bending area, and a second sub-region connected to a second side of the bending area. The circuit layer may comprise a light blocking layer disposed on the substrate, a substrate buffer layer covering the light blocking layer, a semiconductor layer disposed on the substrate buffer layer, a first gate insulating layer covering the semiconductor layer, a first gate conductive layer disposed on the first gate insulating layer, a second gate insulating layer covering the first gate conductive layer, a second gate conductive layer disposed on the second gate insulating layer, an interlayer insulating layer covering the second gate conductive layer, a bending groove formed in the bending area and extending through at least one of the substrate buffer layer, the first gate insulating layer, the second gate insulating layer, or the interlayer insulating layer, and a sub-buffer portion covering the bending groove. The display device may further comprise two or more concave grooves formed in the bending area, and one or more convex portions disposed between the two or more concave grooves.

The main region may comprise a display area in which emission areas are arranged, and a non-display area disposed around the display area. The circuit layer may further comprise a grid formed in at least the display area of the main region and comprising first and second extension grooves which intersect each other, and a main buffer portion disposed in the main region and covering the grid, wherein the main buffer portion may be disposed on a same layer as the sub-buffer portion. Each of the first extension grooves and the second extension grooves may reach a part of at least one of the substrate, the light blocking layer, the first gate conductive layer, or the second gate conductive layer. Each of the substrate buffer layer, the first gate insulating layer, the second gate insulating layer, the interlayer insulating layer, the sub-buffer portion, and the main buffer portion may contain an inorganic insulating material.

Each of the two or more concave grooves may extend through a part of the substrate and extend in a first direction crossing a second direction along which the first sub-region and the second sub-region face each other. The two or more concave grooves may be arranged along the second direction. A portion of the substrate overlapping the bending groove may have a surface with a concavo-convex structure formed by the two or more concave grooves and the one or more convex portions. The sub-buffer portion may cover the portion of the substrate having the surface with the concavo-convex structure. A depth of each of the two or more concave grooves may be less than a thickness of the substrate.

A thickness of a first portion of the sub-buffer portion disposed on the one or more convex portions may be a first thickness. A thickness of a second portion of the sub-buffer portion disposed on a side surface of each of the two or more concave grooves may be a second thickness less than or equal to the first thickness.

The display device may further comprise one or more mask layers disposed on the one or more convex portions. An inclination of the side surface of each of the two or more concave grooves with respect to a bottom surface of the two or more concave grooves may be less than or equal to 90 degrees. The sub-buffer portion may cover the one or more mask layers.

A width of the one or more mask layers may be greater than a width of the one or more convex portions. An edge of the one or more mask layers may protrude beyond the two or more concave grooves.

A circuit layer of the display device according to embodiments may include a grid formed in at least the display area of a main region and including first extension grooves and second extension grooves which intersect each other, a bending groove formed in a bending area of a sub-region, a main buffer portion which covers the grid, and a sub-buffer portion which covers the bending groove.

Each of the first extension grooves and the second extension grooves of the grid may extend through at least one of a substrate buffer layer, a first gate insulating layer, a second gate insulating layer, or an interlayer insulating layer, and may reach a part of at least one of a substrate, a light blocking layer, a first gate conductive layer, or a second gate conductive layer.

Each of the substrate buffer layer, the first gate insulating layer, the second gate insulating layer, and the interlayer insulating layer may include an inorganic insulating material.

According to an embodiment, each of the substrate buffer layer, the first gate insulating layer, the second gate insulating layer, and the interlayer insulating layer including an inorganic insulating material having relatively low elasticity may be partially removed through the use of the grid including first extension grooves and the second extension grooves arranged in a grid form, and crack generation and crack transmission in the inorganic insulating material caused by external impact may be reduced. Accordingly, a risk of damage to the display device due to external impact may be reduced.

Additionally, according to an embodiment, the circuit layer may further include a grid filling layer which fills the grid and includes an organic insulating material.

Accordingly, an organic insulating material having relatively high elasticity may be disposed in a grid form through using the grid and the grid filling layer, and the elasticity of the display device may be improved. Accordingly, even if external impact is applied to the display device, the external impact may be alleviated, or the transmission of the impact may be reduced due to the elasticity of the display device itself. Accordingly, the lifespan and usability of the display device may be enhanced.

According to an embodiment, as the circuit layer includes the main buffer portion which covers the grid and includes an inorganic insulating material, electrical connection through the grid may be blocked, and permeation of oxygen or moisture through the grid and the substrate may be reduced.

According to an embodiment, the circuit layer may include the sub-buffer portion disposed on the same layer as the main buffer portion and covering the bending groove.

According to an embodiment, the circuit layer may further include a buffer separation groove extending through the sub-buffer portion.

In this way, cracks in the sub-buffer portion due to bending stress in the bending area may be prevented.

According to an embodiment, the circuit layer may further include two or more concave grooves formed in the bending area and extending through a part of the substrate, and one or more convex portions disposed therebetween. In this case, a portion of the substrate overlapping the bending groove may have a surface with a concavo-convex structure formed by two or more concave grooves and one or more convex portions.

Accordingly, the sub-buffer portion covering the bending groove may have partially thin thickness due to the concavo-convex structure of the substrate, allowing it to be easily separated. Accordingly, although a mask process and an etching process for separating the sub-buffer portion are not performed, cracks in the sub-buffer portion due to bending stress in the bending area may be prevented from being transmitted to the display area.

As described above, the display device according to an embodiment may have an improved elasticity by including the grid and thus may be robust against external impacts.

In addition, a portion of the substrate of the display device according to an embodiment, which overlaps the bending groove, has a surface with a concavo-convex structure formed by two or more concave grooves and one or more convex portions, so that the sub-buffer portion which is disposed on the same layer as the main buffer portion covering the grid and covers the bending groove may be easily separated. Accordingly, a decrease in lifespan and a decrease in display quality of the display device due to the sub-buffer portion may be prevented.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is a perspective view illustrating a display device according to an embodiment.

FIG. 2 is a plan view illustrating the display device of FIG. 1.

FIG. 3 is a cross-sectional view taken along a line A-A′ of FIG. 2.

FIG. 4 is a layout illustrating a part B of FIG. 2.

FIG. 5 is an equivalent circuit showing a light-emitting pixel driver of FIG. 4 according to an embodiment.

FIG. 6 is a cross-sectional view showing a light-emitting element and first and sixth transistors of FIG. 5.

FIG. 7 is a plan view illustrating a substrate of FIG. 3 according to an embodiment.

FIG. 8 is a layout showing a part C of FIG. 7 according to an embodiment.

FIG. 9 is a cross-sectional view taken along a line D-D′ of FIG. 8.

FIG. 10 is a cross-sectional view taken along a line E-E′ of FIG. 8.

FIG. 11 is a cross-sectional view taken along a line F-F′ of FIG. 8.

FIG. 12 is a layout showing a part C of FIG. 7 according to an embodiment.

FIG. 13 is a cross-sectional view taken along a line G-G′ of FIG. 12.

FIG. 14 is a layout showing a part C of FIG. 7 according to an embodiment.

FIGS. 15, 16, and 17 are cross-sectional views taken along a line H-H′ of FIG. 14 according to an embodiment.

FIGS. 18, 19, 20, 21, and 22 are process diagrams illustrating steps in the method of manufacturing a display device according to an embodiment of FIG. 17.

### DETAILED DESCRIPTION OF THE EMBODIMENTS

The embodiments of the present disclosure will now be described more fully hereinafter with reference to the accompanying drawings. The present disclosure may, however, be provided in different forms and should not be construed as limited to the embodiments set for the herein. Rather, these embodiments are merely provided to ensure the completeness of the present disclosure, and will fully convey the scope of the present disclosure to those skilled in the art.

The same reference numbers indicate the same components throughout the present disclosure. In the accompanying drawings, the thickness of layers and regions may be exaggerated for clarity.

It will also be understood that when a layer is referred to as being “on” another layer or substrate, it can be directly on the other layer or substrate, or intervening layers may also be present. In contrast, when an element is referred to as being “directly on” another element, there may be no intervening elements present between those two elements.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below a second object, or be disposed on a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” or “including” are used, they may specify the presence of stated features, integers, steps, operations, elements or components, but do not preclude the presence or addition of other features, integers, steps, operations, elements, components, or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings of the present disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the present disclosure will be described with reference to the accompanying drawings.

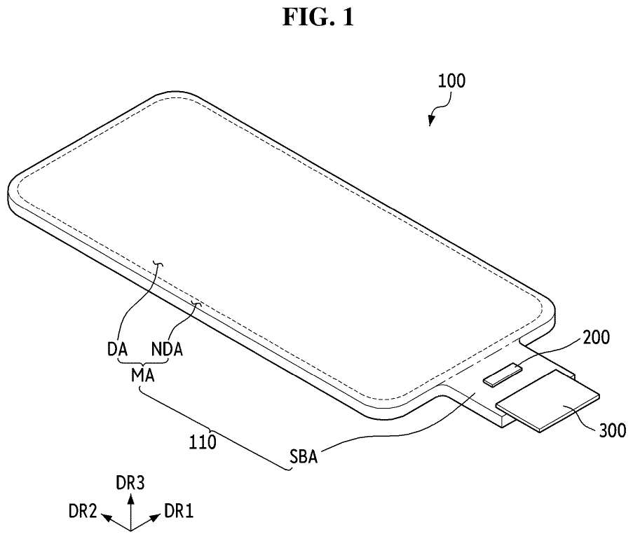

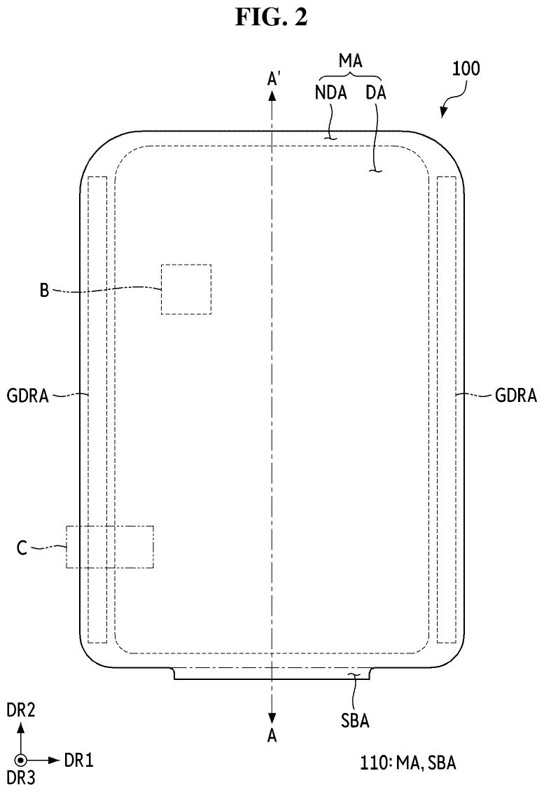

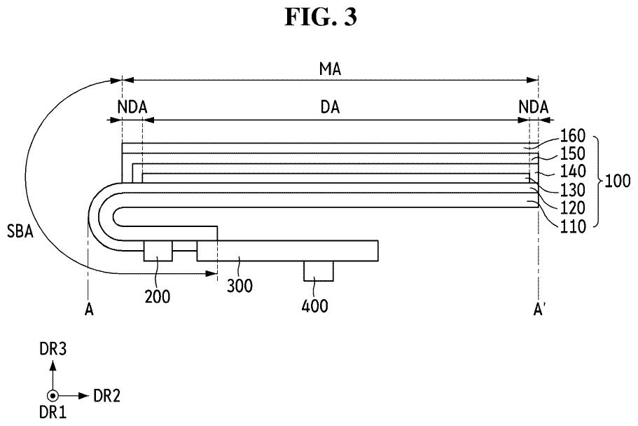

FIG. 1 is a perspective view illustrating a display device according to an embodiment. FIG. 2 is a plan view illustrating the display device of FIG. 1. FIG. 3 is a cross-sectional view taken along a line A-A′ of FIG. 2.

Referring to FIGS. 1 and 2, a display device 100 according to an embodiment, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light-emitting display device such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 100 is an organic light-emitting display device. However, the present disclosure is not limited thereto, and may be applied to a display device including an organic insulating material, an organic light-emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it may be curved, bent, folded, or rolled.

As illustrated in FIGS. 1, 2 and 3, the display device 100 according to an embodiment may include a substrate 110.

The substrate 110 may include a main region MA corresponding to a display surface of the display device 100 and a sub-region SBA protruding from one side of the main region MA.

As shown in FIG. 2, the main region MA may include a display area DA positioned in the most central region thereof, and a non-display area NDA disposed around the display area DA.

The display area DA may, in a plan view, be formed in a rectangular shape having short sides extending in a first direction DR1 and long sides extending in a second direction DR2 crossing the first direction DR1. The corner where the short side in the first direction DR1 and the long side in the second direction DR2 meet may be rounded to have a predetermined curvature or may be right-angled. The planar shape of the display area DA is not limited to the rectangular shape, and may be formed in another polygonal shape, a circular shape or an elliptical shape.

The non-display area NDA may be disposed at the edge of the main region MA to surround the display area DA.

The sub-region SBA may be a region protruding from one side of the non-display area NDA of the main region MA and extending along the second direction DR2.

The display device 100 may include a display driving circuit 200 disposed on the sub-region SBA, and the display circuit board 300 may be bonded to one surface of the sub-region SBA.

FIGS. 2 and 3 illustrate the display device 100 with a part of the sub-region SBA in a bent state.

As shown in FIGS. 2 and 3, the sub-region SBA may be bent, so that a part of the sub-region SBA may be disposed on a rear surface of the display device 100.

Referring to FIG. 3, the display device 100 according to an embodiment includes the substrate 110, a circuit layer 120 disposed on the substrate 110, and an element layer 130 disposed on the circuit layer 120.

The display device 100 according to an embodiment may further include an encapsulation layer 140 disposed on the element layer 130, and a touch sensor layer 150 disposed on the encapsulation layer 140.

Also, the display device 100 according to an embodiment may further include a polarization layer 160 disposed on the touch sensor layer 150 to reduce reflection of external light.

The substrate 110 may be formed of an insulating material such as a polymer resin. For example, the substrate 110 may be formed of polyimide. The substrate 110 may be a flexible substrate which can be bent, folded or rolled.

The substrate 110 may be formed of an insulating material such as glass or the like.

The substrate 110 may include the main region MA and the sub-region SBA. The main region MA may include the display area DA and the non-display area NDA.

The display device 100 may further include the display driving circuit 200 disposed in the sub-region SBA. A display circuit board 300 may be bonded to one surface of the sub-region SBA, and a touch driving circuit 400 may be mounted on the display circuit board 300.

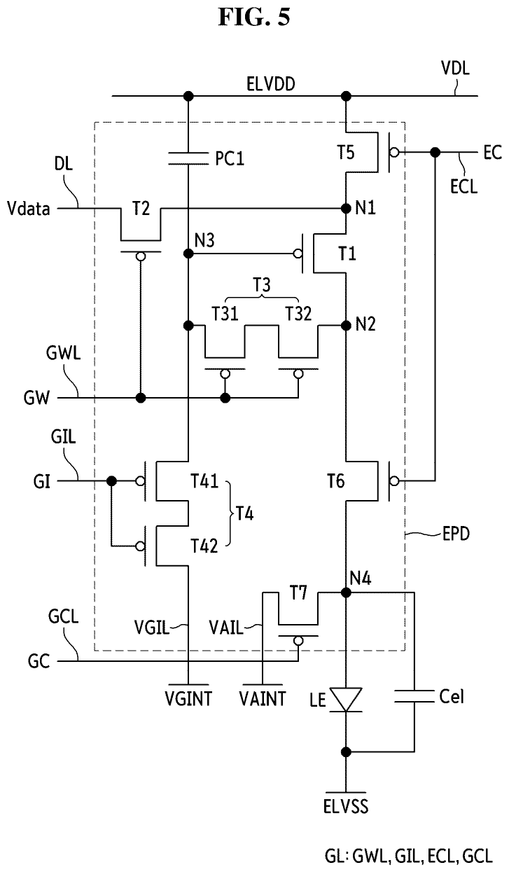

The display driving circuit 200 may supply a data signal Vdata (see FIG. 5) to data lines DL (see FIG. 5) of the circuit layer 120.

The display circuit board 300 may be connected to signal pads disposed at the edge of the sub-region SBA and may be electrically connected to the circuit layer 120 or the display driving circuit 200.

The touch driving circuit 400 may be electrically connected to the touch sensor layer 150.

The circuit layer 120 may include insulating layers, conductive layers, and one or more semiconductor layers. The insulating layers may be interposed between the conductive layers and one or more semiconductor layers. The circuit layer 120 may include transistors formed with one or more semiconductor layers and the conductive layers, and signal lines, each of which is provided with at least one of the conductive layers.

The element layer 130 may include light-emitting elements.

The encapsulation layer 140 may cover the circuit layer 120 and the element layer 130, and may block permeation of oxygen or moisture into the element layer 130.

The touch sensor layer 150 may include touch electrodes and touch lines connected thereto.

The touch driving circuit 400 may apply a touch driving signal to driving lines of the touch sensor layer 150, and receive a touch sensing signal from sensing lines. Further, the touch driving circuit 400 may detect changes in charge of capacitances based on the touch sensing signal, thereby determining whether a user has touched or approached. The user's touch means that an object such as a pen or a user's finger is in direct contact with the top surface of the cover window disposed on the touch sensor layer. The user's approach means that the object such as the pen or the user's finger hovers over the top surface of the cover window. The touch driving circuit 400 may output touch data including the user's touch coordinates to a main processor.

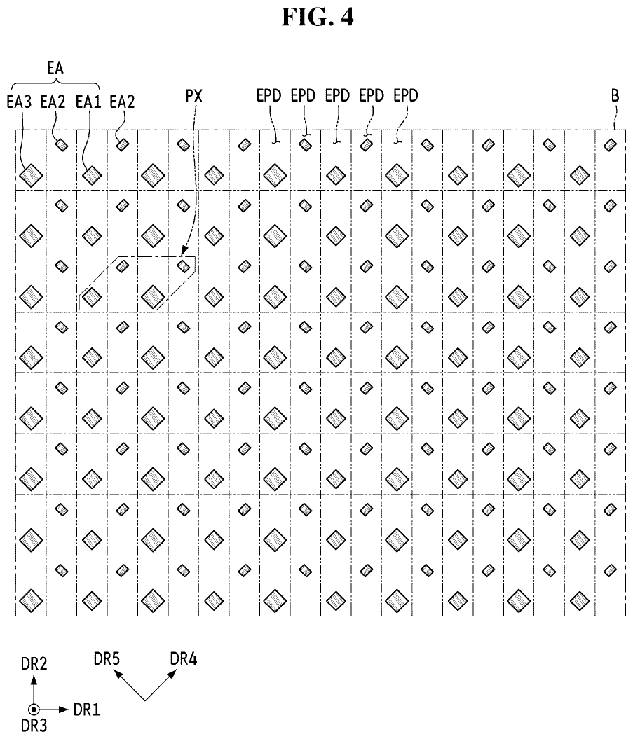

FIG. 4 is a layout illustrating a part B of FIG. 2.

Referring to FIG. 4, the display area DA of the display device 100 according to an embodiment may include emission areas EA. In addition, the display area DA may further include a non-emission area disposed in a gap between the emission areas EA.

The element layer 130 (see FIG. 3) may include light-emitting elements LE (see FIG. 5) respectively disposed in the emission areas EA.

The circuit layer 120 (see FIG. 3) may include light-emitting pixel drivers EPD arranged side by side in the first direction DR1 and the second direction DR2 in the main region MA. Each of the light-emitting pixel drivers EPD may be electrically connected to the corresponding light-emitting elements LE (see FIG. 5) of the element layer 130.

The emission areas EA may have a rhombus shape or a rectangular shape in a plan view. However, this is only an example, and the planar shape of the emission areas EA according to an embodiment is not limited to that illustrated in FIG. 4. That is, in a plan view, the emission areas EA may have a polygonal shape such as a quadrangle, a pentagon, and a hexagon, or may have a circular or elliptical shape including the edge of a curve.

The emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to approximately 750 nm. The second color may be green having a wavelength band of approximately 480 nm to approximately 560 nm. The third color may be blue having a wavelength band of approximately 370 nm to approximately 460 nm.

The first emission areas EA1 and the third emission areas EA3 may be alternately disposed in at least one of the first direction DR1 or the second direction DR2.

The second emission areas EA2 may be arranged side parallel to each other in at least one of the first direction DR1 or the second direction DR2.

In addition, the second emission areas EA2 may be adjacent to the first emission areas EA1 and the third emission areas EA3 in diagonal directions DR4 and DR5 crossing the first direction DR1 and the second direction DR2.

Pixels PX displaying their own luminance and colors may be provided by the first emission area EA1, the second emission area EA2, and the third emission area EA3 adjacent to each other among these emission areas EA.

In other words, each of the pixels PX may be a basic unit for displaying various colors including white with a predetermined luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 5 is an equivalent circuit showing the light-emitting pixel driver of FIG. 4 according to an embodiment.

Referring to FIG. 5, the light-emitting pixel drivers EPD of the circuit layer 120 may be electrically connected between a first power source ELVDD and the light-emitting elements LE of the element layer 130.

One of the light-emitting elements LE of the element layer 130 may be electrically connected between one of the light-emitting pixel drivers EPD of the circuit layer 120 and a second power source ELVSS.

That is, the anode electrode of the light-emitting element LE is electrically connected to the light-emitting pixel driver EPD, and the cathode electrode of the light-emitting element LE may be connected to a second power source ELVSS to be applied with a voltage of the second power source ELVSS having a voltage level lower than the first power source ELVDD.

A capacitor Ce1 connected in parallel with the light-emitting element LE may refer to a parasitic capacitance between the anode electrode and the cathode electrode.

The circuit layer 120 may include a first power line VDL for transmitting the voltage of the first power source ELVDD, a gate initialization voltage line VGIL for transmitting a gate initialization voltage VGINT, and an anode initialization voltage line VAIL for transmitting an anode initialization voltage VAINT.

The circuit layer 120 may include gate lines GL electrically connected to at least one gate electrode of transistors T1 to T7 provided in each of the light-emitting pixel drivers EPD.

The gate lines GL may include a scan write line GWL for transmitting a scan write signal GW, a scan initialization line GIL for transmitting a scan initialization signal GI, an emission control line ECL for transmitting an emission control signal EC, and a gate control line GCL for transmitting a gate control signal GC.

One light-emitting pixel driver EPD of the circuit layer 120 may include a first transistor T1 configured to generate a driving current for driving the light-emitting element LE, two or more transistors T2 to T7 electrically connected to the first transistor T1, and at least one pixel capacitor PC1.

The first transistor T1 may be electrically connected between a first node N1 and a second node N2. The first node N1 is electrically connected to a first electrode (e.g., source electrode) of the first transistor T1. The second node N2 is electrically connected to a second electrode (e.g., drain electrode) of the first transistor T1.

The first node N1 may be electrically connected to the first power line VDL through the fifth transistor T5.

The second node N2 may be electrically connected to the anode electrode of the light-emitting element LE through the sixth transistor T6.

The pixel capacitor PC1 may be electrically connected between the first power line VDL and a third node N3. The third node N3 is electrically connected to a gate electrode of the first transistor T1.

That is, the gate electrode of the first transistor T1 may be electrically connected to the first power line VDL through the pixel capacitor PC1.

Accordingly, the potential of the gate electrode of the first transistor T1 may be maintained by the voltage stored in the pixel capacitor PC1.

The second transistor T2 may be electrically connected between the data line DL and the first node N1.

The second transistor T2 may be electrically connected between the first electrode of the first transistor T1 and the data line DL.

That is, the first electrode of the first transistor T1 may be electrically connected to the data line DL through the second transistor T2.

The second transistor T2 may be turned on by the scan write signal GW applied through the scan write line GWL.

The fifth transistor T5 may be electrically connected between the first node N1 and the first power line VDL.

The sixth transistor T6 may be electrically connected between the second node N2 and a fourth node N4. The fourth node N4 is electrically connected to the anode electrode of the light-emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light-emitting element LE.

The fifth transistor T5 and the sixth transistor T6 may be turned on by the emission control signal EC applied through the emission control line ECL.

When the data signal Vdata of the data line DL is transmitted to the first electrode of the first transistor T1 through the turned-on second transistor T2, a voltage difference between the gate electrode of the first transistor T1 and the first electrode of the first transistor T1 may be a difference in voltages between the first power source ELVDD and the data signal Vdata.

When the voltage difference between the gate electrode of the first transistor T1 and the first electrode of the first transistor T1, i.e., the gate-source voltage difference, becomes equal to or greater than a threshold voltage, the first transistor T1 may be turned on, and generate a driving current of the first transistor T1 corresponding to the data signal Vdata.

Subsequently, when the fifth transistor T5 and the sixth transistor T6 are turned on, the first power source ELVDD, the first transistor T1, the light-emitting element LE, and the second power source ELVSS may be connected in series. Accordingly, the driving current of the first transistor T1 corresponding to the data signal Vdata may be supplied to the light-emitting element LE.

Accordingly, the light-emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

A first electrode of the first sub-transistor T31 may be connected to the gate electrode of the first transistor T1, a second electrode of the first sub-transistor T31 may be connected to a first electrode of the second sub-transistor T32, and a second electrode of the second sub-transistor T32 may be connected to the second electrode of the first transistor T1.

In this way, it is possible to prevent the potential of the gate electrode of the first transistor T1 from changing due to the leakage current caused by the third transistor T3 that is not turned on.

The first sub-transistor T31 and the second sub-transistor T32 may be turned on by the scan write signal GW through the scan write line GWL.

When the first sub-transistor T31 and the second sub-transistor T32 are turned on, a voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may include a plurality of sub-transistors connected in series. For example, the fourth transistor T4 may include a third sub-transistor T41 and a fourth sub-transistor T42.

A first electrode of the third sub-transistor T41 may be connected to the gate electrode of the first transistor T1, a second electrode of the third sub-transistor T41 may be connected to a first electrode of the fourth sub-transistor T42, and a second electrode of the fourth sub-transistor T42 may be connected to the gate initialization voltage line VGIL.

In this way, it is possible to prevent the potential of the gate electrode of the first transistor T1 from changing due to the leakage current caused by the fourth transistor T4 that is not turned on.

The third sub-transistor T41 and the fourth sub-transistor T42 may be turned on by the scan initialization signal GI applied through the scan initialization line GIL.

When the third sub-transistor T41 and the fourth sub-transistor T42 are turned on, the potential of the third node N3 may be initialized to the gate initialization voltage VGINT.

The seventh transistor T7 may be electrically connected between the fourth node N4 and the anode initialization voltage line VAIL. That is, the seventh transistor T7 may be electrically connected between the anode electrode of the light-emitting element LE and the anode initialization voltage line VAIL.

The seventh transistor T7 may be turned on by the gate control signal GC applied through the gate control line GCL.

Through the turned-on seventh transistor T7, the potential of the fourth node N4 may be initialized to the anode initialization voltage VAINT.

As shown in FIG. 5, according to an embodiment, the first to seventh transistors T1 to T7 may be provided as P-type MOSFETs. However, the present disclosure is not limited thereto, and some transistors among the first to seventh transistors T1 to T7 may be provided as N-type MOSFETs and the other transistors may be provided as P-type MOSFETs. In addition, the first to seventh transistors T1 to T7 may be provided as N-type MOSFETs.

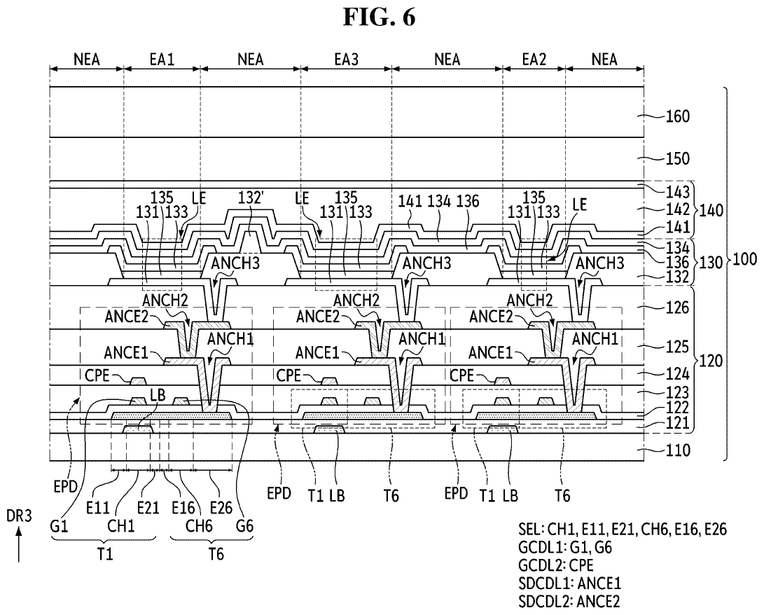

FIG. 6 is a cross-sectional view showing the light-emitting element and first and sixth transistors of FIG. 5.

Referring to FIG. 6, the display device 100 according to an embodiment may include the substrate 110, the circuit layer 120 on the substrate 110, and the element layer 130 on the circuit layer 120.

The display device 100 according to an embodiment may further include the encapsulation layer 140 on the element layer 130, the touch sensor layer 150 on the encapsulation layer 140, and the polarization layer 160 on the touch sensor layer 150.

According to an embodiment, the circuit layer 120 may include a light blocking layer LB disposed on the substrate, a substrate buffer layer 121 covering the light blocking layer LB and disposed on the substrate 110, a semiconductor layer SEL disposed on the substrate buffer layer 121, a first gate insulating layer 122 covering the semiconductor layer SEL, a first gate conductive layer GCDL1 disposed on the first gate insulating layer 122, a second gate insulating layer 123 covering the first gate conductive layer GCDL1, a second gate conductive layer GCDL2 disposed on the second gate insulating layer 123, and an interlayer insulating layer 124 covering the second gate conductive layer GCDL2.

In addition, the circuit layer 120 may further include a first source-drain conductive layer SDCDL1 disposed on the interlayer insulating layer 124, a first planarization layer 125 covering the first source-drain conductive layer SDCDL1, a second source-drain conductive layer SDCDL2 disposed on the first planarization layer 125, and a second planarization layer 126 covering the second source-drain conductive layer SDCDL2.

The circuit layer 120 may include the light-emitting pixel drivers EPD, each of which is respectively disposed in an area corresponding to each of the emission areas EA.

Each of the light-emitting pixel drivers EPD may include the first transistor T1, the second to seventh transistors T2 to T7 (see FIG. 5) electrically connected to the first transistor T1, and at least one pixel capacitor PC1 (see FIG. 5).

A channel portion, a first electrode portion, and a second electrode portion of each of the plurality of transistors T1 to T7 may be disposed in a semiconductor layer on the substrate buffer layer 121.

That is, channel portions CH1 and CH7, first electrode portions E11 and E17, and second electrode portions E21 and E27 of the first to seventh transistors T1 to T7 may be disposed in a semiconductor layer SEL on the substrate buffer layer 121.

In the first transistor T1 and the sixth transistor T6, each of the first electrode portions E11 and E16 may be connected to a first end of each of the channel portions CH1 and CH6, and each of the second electrode portions E21 and E26 may be connected to a second end, which is an opposite side to the first end with respect to the channel portions CH1 and CH6, of each of the channel portions CH1 and CH6. The light blocking layer LB is disposed below the channel portion CH1 of the first transistor T1.

The second electrode portion E21 of the first transistor T1 may be connected to the first electrode portion E16 of the sixth transistor T6.

The gate electrode of each of the plurality of transistors T1 to T7 may be disposed on the first gate insulating layer 122.

That is, gate electrodes G1 and G7 of the first to seventh transistors T1 to T7 may be formed of the first gate conductive layer and disposed on the first gate insulating layer 122.

In the first transistor T1 and the sixth transistor T6, the gate electrodes G1 and G6 may overlap the channel portions CH1 and CH6, respectively.

The second transistor T2, the first sub-transistor T31, the second sub-transistor T32, the third sub-transistor T41, the fourth sub-transistor T42, the fifth transistor T5, and the seventh transistor T7 of FIG. 5 may have the same or similar configuration as the first transistor T1 and the sixth transistor T6, so that redundant description will be omitted below.

A capacitor electrode CPE may be formed of the second gate conductive layer GCDL2 and disposed on the second gate insulating layer 123. The capacitor electrode CPE may overlap the gate electrode G1 of the first transistor T1.

The capacitor electrode CPE may be electrically connected to the first power line VDL (see FIG. 5).

Accordingly, the pixel capacitor PC1 (see FIG. 5) may be formed in an overlapping area between the capacitor electrode CPE and the gate electrode G1 of the first transistor T1.

The first source-drain conductive layer SDCDL1 disposed on the interlayer insulating layer 124 may include a first anode connection electrode ANCE1.

The first anode connection electrode ANCE1 may be electrically connected to the second electrode portion E26 of the sixth transistor T6 through a first anode connection hole ANCH1.

The second source-drain conductive layer SDCDL2 disposed on the first planarization layer 125 may include a second anode connection electrode ANCE2.

The second anode connection electrode ANCE2 may be electrically connected to the first anode connection electrode ANCE1 through a second anode connection hole ANCH2.

An anode electrode 131 of the element layer 130 may be disposed on the second planarization layer 126, and may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

The element layer 130 on the circuit layer 120 may include the light-emitting elements LE. Each of the light-emitting elements LE is respectively disposed in the emission areas EA1, EA2, and EA3.

Each of the light-emitting elements LE may include a structure in which a light-emitting layer 133 is disposed between the anode electrode 131 and a cathode electrode 134 facing each other.

In accordance with an embodiment, the element layer 130 may include the anode electrodes 131 respectively disposed in the emission areas EA, a pixel defining layer 132 disposed in the non-emission area NEA and covering the edge of the anode electrode 131, a spacer layer 132′ disposed on a part of the pixel defining layer 132, the light-emitting layers 133 respectively disposed on the anode electrodes 131, and the cathode electrode 134 disposed on the light-emitting layers 133, the pixel defining layer 132, and the spacer layer 132′.

Each of the light-emitting elements LE may further include a first common layer 135 disposed between the anode electrodes 131 and the light-emitting layers 133, and a second common layer 136 disposed between the light-emitting layers 133 and the cathode electrode 134.

The encapsulation layer 140 may be disposed on the element layer 130.

The encapsulation layer 140 is provided to block the permeation of oxygen or moisture into the element layer 130 and to reduce electrical or physical impact to the circuit layer 120 and the element layer 130.

The encapsulation layer 140 may include a first encapsulation layer 141 disposed on the element layer 130 and containing an inorganic insulating material, a second encapsulation layer 142 disposed on the first encapsulation layer 141 and containing an organic insulating material, and a third encapsulation layer 143 covering the second encapsulation layer 142 and containing an inorganic insulating material.

The touch sensor layer 150 may be disposed on the encapsulation layer 140.

The polarization layer 160 may be disposed on the touch sensor layer 150.

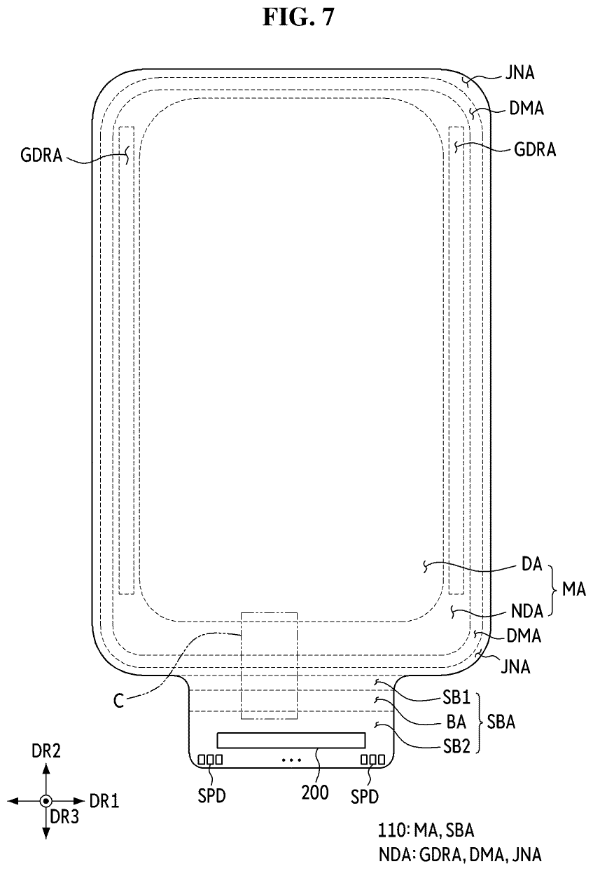

FIG. 7 is a plan view illustrating a substrate of FIG. 3 according to an embodiment.

Referring to FIG. 7, the substrate 110 of the display device 100 according to an embodiment may include the main region MA corresponding to the display surface, and the sub-region SBA protruding from one side of the main region MA.

The main region MA may include the display area DA in which the emission areas EA are arranged, and the non-display area NDA surrounding the display area DA.

The non-display area NDA may include a gate driving circuit area GDRA disposed on at least one side of the display area DA.

The circuit layer 120 (see FIG. 3) may include a gate driving circuit disposed in the gate driving circuit area GDRA and electrically connected to the gate lines GL (see FIG. 5).

The non-display area NDA may further include a dam area DMA surrounding the display area DA, and a junction area JNA surrounding the dam area DMA.

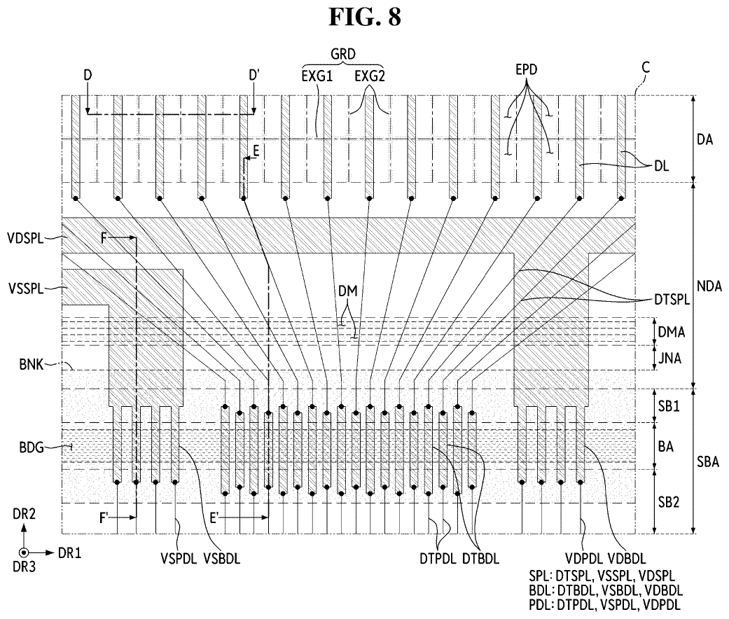

At least one dam portion DM (see FIGS. 8, 10 and 11) surrounding the display area DA may be arranged in the dam area DMA.

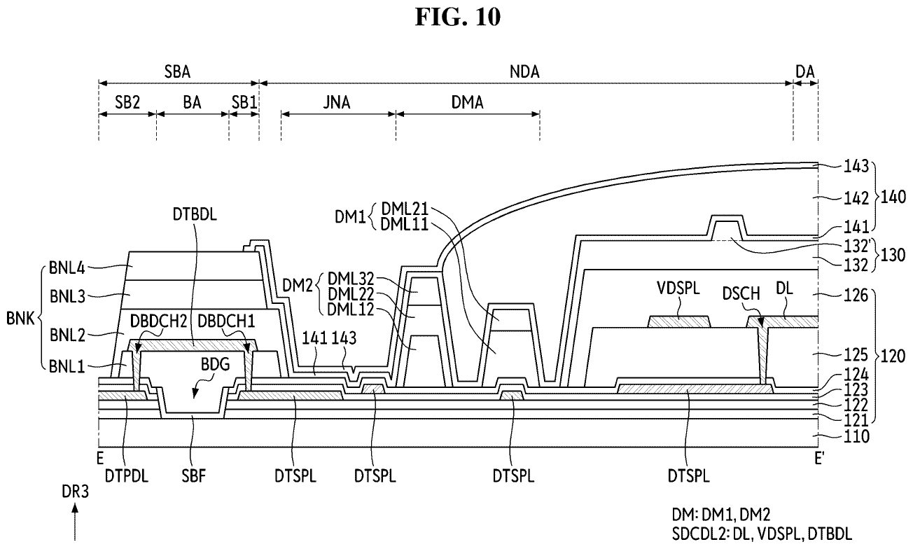

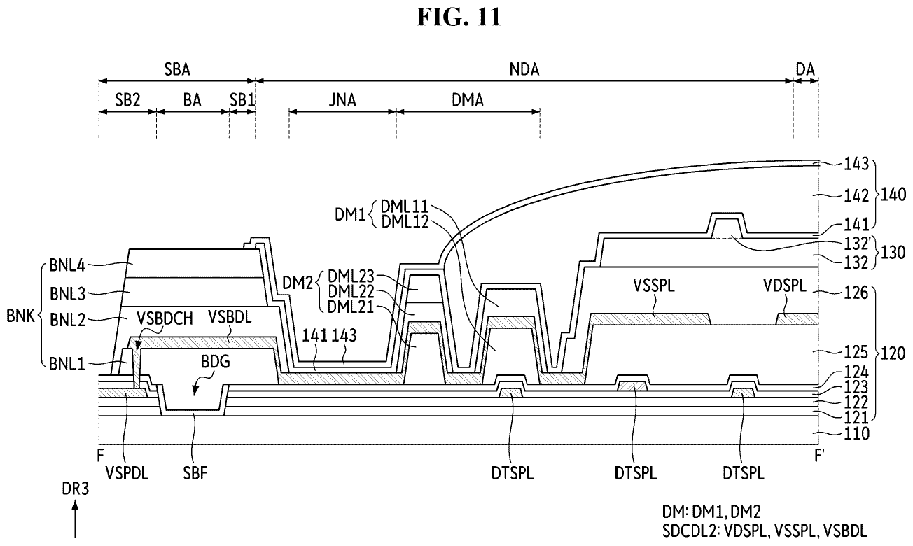

At least one dam portion DM may each include a structure in which two or more dam layers DML11, DML21, DML12, DML22, and DML32 (see FIGS. 10 and 11), each of which includes an organic insulating material, are stacked. Each of the dam layers may be formed with a relatively large thickness by including an organic insulating material. In addition, valleys where the inorganic insulating material is exposed may be provided on both sides of at least one dam portion DM. Accordingly, the arrangement range of the second encapsulation layer 142 of the encapsulation layer 140 (see FIG. 6) may be limited by the at least one dam portion DM.

The junction area JNA may be provided with a structure in which the inorganic insulating material of the encapsulation layer 140 (see FIG. 6) is in contact with the inorganic insulating material in the circuit layer 120 (see FIG. 6).

For example, each of the substrate buffer layer 121 (see FIG. 6), the first gate insulating layer 122 (see FIG. 6), the second gate insulating layer 123 (see FIG. 6), and the interlayer insulating layer 124 (see FIG. 6) in the circuit layer 120 may include one or more inorganic insulating materials selected from silicon nitride, silicon oxynitride, silicon oxide, titanium oxide, and aluminum oxide.

Further, each of the first encapsulation layer 141 (see FIG. 6) and the third encapsulation layer 143 (see FIG. 6) of the encapsulation layer 140 may include one or more inorganic insulating materials selected from silicon nitride, silicon oxynitride, silicon oxide, titanium oxide, and aluminum oxide.

The first encapsulation layer 141 (see FIG. 6) of the encapsulation layer 140 may be in contact with the interlayer insulating layer 124 of the circuit layer 120 in the junction area JNA.

In addition, the third encapsulation layer 143 (see FIG. 6) of the encapsulation layer 140 may be in contact with the first encapsulation layer 141 or the interlayer insulating layer 124 of the circuit layer 120 in the junction area JNA.

Accordingly, since the organic insulating materials of the circuit layer 120 and the element layer 130 may be sealed with a junction structure of inorganic insulating materials, the occurrence of a pathway through which an oxygen or moisture is permeated may be delayed.

The sub-region SBA may include a bending area BA that is transformed into a bent shape, a first sub-region SB1 disposed between a first side of the bending area BA and the main region MA, and a second sub-region SB2 connected to a second side of the bending area BA, which is an opposite side to the first side with respect to the bending area BA.

When the bending area BA is transformed into a bent shape, the second sub-region SB2 may be disposed below the substrate 110 and overlap the main region MA.

The display driving circuit 200 may be disposed in the second sub-region SB2.

Signal pads SPD bonded to the display circuit board 300 may be disposed at one edge of the second sub-region SB2.

FIG. 8 is a layout diagram showing part C of FIG. 7 according to an embodiment.

Referring to FIG. 8, the circuit layer 120 of the display device 100 according to an embodiment may include a grid GRD formed in at least a part of the main region MA and a bending groove BDG formed in the bending area BA of the sub-region SBA.

The grid GRD may include first extension grooves EXG1 and second extension grooves EXG2 that intersect each other. That is, the grid GRD may include the first extension grooves EXG1 extending in the first direction DR1 and the second extension grooves EXG2 extending in the second direction DR2.

The bending groove BDG may extend parallel to one side of the main region MA from which the sub-region SBA protrudes. That is, the bending groove BDG may extend in the first direction DR1.

According to an embodiment, the circuit layer 120 may further include the light-emitting pixel drivers EPD that are electrically connected to the light-emitting elements LE (see FIG. 6) of the element layer 130 (see FIG. 6), respectively, and the data lines DL that transmit the data signal Vdata (see FIG. 5) to the light-emitting pixel drivers EPD.

In the second direction DR2 along which the second extension grooves EXG2 extend, one or more light-emitting pixel drivers EPD may be disposed between the first extension grooves EXG1.

That is, the first extension grooves EXG1 may be formed at the boundary of the light-emitting pixel drivers EPD and spaced apart from each other with intervals of one or more light-emitting pixel drivers EPD.

In the first direction DR1 along which the first extension grooves EXG1 extend, one or more light-emitting pixel drivers EPD may be disposed between the second extension grooves EXG2.

That is, the second extension grooves EXG2 may be formed at the boundary of the light-emitting pixel drivers EPD and spaced apart from each other with intervals of one or more light-emitting pixel drivers EPD.

According to an embodiment, the circuit layer 120 may further include supply lines SPL disposed in the non-display area NDA and extending from the periphery of the display area DA to the first sub-region SB1, bending lines BDL that intersect the bending area BA, and pad lines PDL disposed in the second sub-region SB2.

The supply lines SPL may include data supply lines DTSPL electrically connected to the data lines DL and transmitting the data signal Vdata (see FIG. 5), a first power supply line VDSPL transmitting the voltage of the first power source ELVDD (see FIG. 5), and a second power supply line VSSPL transmitting the voltage of the second power source ELVSS (see FIG. 5).

The bending lines BDL may include data bending lines DTBDL electrically connected to the data supply lines DTSPL, a first power bending line VDBDL electrically connected to the first power supply line VDSPL, and a second power bending line VSBDL electrically connected to the second power supply line VSSPL.

The pad lines PDL may include data pad lines DTPDL electrically connected between the data bending lines DTBDL and the display driving circuit 200 (see FIG. 7), a first power pad line VDPDL electrically connected to the first power bending line VDBDL and extending to at least one of the signal pads SPD (see FIG. 7), and a second power pad line VSPDL electrically connected to the second power bending line VSBDL and extending to at least another one of the signal pads SPD (see FIG. 7).

The display device 100 according to an embodiment may further include at least one dam portion DM disposed in the dam area DMA.

The display device 100 according to an embodiment may further include a bank BNK covering the bending groove BDG in the bending area BA.

The bank BNK may cover a first side of the bending area BA and may also be disposed on a part of the first sub-region SB1 and the non-display area NDA. Additionally, the bank BNK may cover a second side of the bending area BA, which is the opposite side to the first side of the bending area BA, and may also be disposed on a part of the second sub-region SB2.

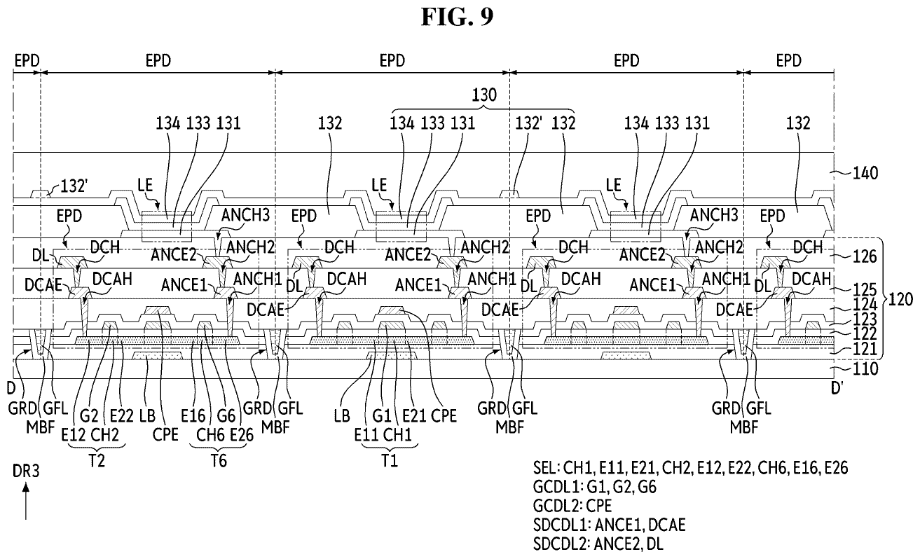

FIG. 9 is a cross-sectional view taken along a line D-D′ of FIG. 8.

Referring to FIG. 9, the grid GRD may partially extend through the insulating layers 121 to 124 of the circuit layer 120 disposed on the substrate 110 and including an inorganic insulating material.

That is, each of the first extension grooves EXG1 and the second extension grooves EXG2 provided in the grid GRD may partially extend through the substrate buffer layer 121, the first gate insulating layer 122, the second gate insulating layer 123, and the interlayer insulating layer 124.

Accordingly, each of the first extension grooves EXG1 and the second extension grooves EXG2 may reach a part of at least one of the substrate 110, the light blocking layer LB, the first gate conductive layer GCDL1, or the second gate conductive layer GCDL2.

That is, in the process of forming the grid GRD, the light blocking layer LB, the first gate conductive layer GCDL1, and the second gate conductive layer GCDL2 may be used as an etch blocking layer.

Accordingly, the first gate insulating layer 122 and the substrate buffer layer 121 disposed below a portion of the first gate conductive layer GCDL1 that overlaps the grid GRD may remain due to the first gate conductive layer GCDL1.

In addition, the second gate insulating layer 123, the first gate insulating layer 122, and the substrate buffer layer 121 disposed below a portion of the second gate conductive layer GCDL2 that overlaps the grid GRD may remain due to the second gate conductive layer GCDL2.

According to an embodiment, the circuit layer 120 may further include a main buffer portion MBF disposed in the main region MA and covering the grid GRD.

The main buffer portion MBF may include an inorganic insulating material.

In this way, by covering the grid GRD with the main buffer portion MBF, the permeation of oxygen or moisture through the substrate 110 and the grid GRD may be delayed.

According to an embodiment, the circuit layer 120 may further include a grid filling layer GFL disposed on the main buffer portion MBF and filling the grid GRD.

The grid filling layer GFL may include an organic insulating material.

As an example, the grid filling layer GFL may be provided together with the first planarization layer 125 including an organic insulating material. In this way, the number of stacking processes may be reduced, and the manufacturing process of the display device 100 may be further simplified.

As another example, the grid filling layer GFL may be provided before forming the first source-drain conductive layer SDCDL1 on the interlayer insulating layer 124, and the first planarization layer 125 may be provided after forming the first source-drain conductive layer SDCDL1 on the interlayer insulating layer 124. In this way, since the first source-drain conductive layer may be disposed on the grid filling layer GFL, the placement of the first source-drain conductive layer SDCDL1 may be facilitated.

As described above, since the display device 100 according to an embodiment includes the grid filling layer GFL that fills the grid GRD and includes an organic insulating material, and the organic insulating material has higher elasticity than the inorganic insulating material, deformation or damage to the display device 100 due to external impact may be reduced.

According to an embodiment, the data line DL may be formed of the second source-drain conductive layer SDCDL2.

The data line DL may be electrically connected to a first electrode portion E12 of the second transistor T2 through a data connection auxiliary electrode DCAE.

The data connection auxiliary electrode DCAE may be formed of the first source-drain conductive layer SDCDL1 and may be electrically connected to the first electrode portion E12 of the second transistor T2 through a data connection auxiliary hole DCAH.

The data connection auxiliary hole DCAH may extend through the interlayer insulating layer 124, the second gate insulating layer 123, and the first gate insulating layer 122.

The data line DL may be electrically connected to the data connection auxiliary hole DCAE through a data connection hole DCH extending through the first planarization layer 125.

FIG. 10 is a cross-sectional view taken along a line E-E′ of FIG. 8. FIG. 11 is a cross-sectional view taken along a line F-F′ of FIG. 8.

Referring to FIGS. 10 and 11, each of the data supply lines DTSPL may be formed of the first gate conductive layer GCDL1 (see FIG. 9) which is disposed on the first gate insulating layer 122 or of the second gate conductive layer GCDL2 (see FIG. 9) which is disposed on the second gate insulating layer 123.

The data line DL may be formed of the second source-drain conductive layer SDCDL2 (see FIG. 9) which is on the first planarization layer 125.

As illustrated in FIG. 10, the data line DL may be electrically connected to the data supply line DTSPL through a data supply connection hole DSCH.

The data supply connection hole DSCH may extend through the first planarization layer 125 and the interlayer insulating layer 124, or may extend through the first planarization layer 125, the interlayer insulating layer 124, and the second gate insulating layer 123.

As illustrated in FIGS. 10 and 11, the first power supply line VDSPL may be formed of the first source-drain conductive layer SDCDL1 (see FIG. 9) which is disposed on the interlayer insulating layer 124 or of the second source-drain conductive layer SDCDL2 (see FIG. 9) which is disposed on the first planarization layer 125.

As illustrated in FIG. 11, the second power supply line VSSPL may be formed of the first source-drain conductive layer SDCDL1 (see FIG. 9) which is disposed on the interlayer insulating layer 124 or of the second source-drain conductive layer SDCDL2 (see FIG. 9) which is disposed on the first planarization layer 125.

Each of at least one dam portion DM disposed in the dam area DMA may include two or more dam layers DML11, DML21, DML12, DML22, and DML32 stacked on each other.

Each of the two or more dam layers DML11, DML21, DML12, DML22, and DML32 may include an organic insulating material.

For example, the at least one dam portion DM may include a first dam portion DM1 surrounding the display area DA and a second dam portion DM2 surrounding the first dam portion DM1.

The first dam layer DML11 of the first dam portion DM1 may be disposed on the same layer as the first planarization layer 125. The second dam layer DML21 of the first dam portion DM1 may be disposed on the same layer as one of the second planarization layer 126, the pixel defining layer 132, and the spacer layer 132′.

The first dam layer DML12 of the second dam portion DM2 may be disposed on the same layer as the first planarization layer 125. Each of the second dam layer DML22 and the third dam layer DML32 of the second dam portion DM2 may be disposed on the same layer as one of the second planarization layer 126, the pixel defining layer 132, and the spacer layer 132′.

According to an embodiment, the first encapsulation layer 141 may be in contact with the interlayer insulating layer 124 in an area between the first and the second dam portions DM1 and DM2, and in an area corresponding to the junction area JNA.

The second encapsulation layer 142 may be selectively placed within a region surrounded by at least one dam portion DM disposed in the dam area DMA. That is, the second encapsulation layer 142 may not be disposed outside the dam area DMA.

Thus, the third encapsulation layer 143 may be in contact with the first encapsulation layer 141 or the interlayer insulating layer 124 in the junction area JNA.

That is, a junction structure of inorganic insulating materials formed by the interlayer insulating layer 124, the first encapsulation layer 141, and the third encapsulation layer 143 may be provided in the junction area JNA. Accordingly, the junction structure may block the permeation of moisture or oxygen through the organic insulating material.

The circuit layer 120 of the display device 100 according to an embodiment may include the bending groove BDG disposed in the bending area BA.

The bending groove BDG is provided to remove the inorganic insulating material disposed in the bending area BA that is transformed into a bent shape.

That is, the bending groove BDG may extend through the insulating layers 121 to 124 of the circuit layer 120 which are disposed on the substrate 110 and include an inorganic insulating material.

As an example, the bending groove BDG may extend through the substrate buffer layer 121, the first gate insulating layer 122, the second gate insulating layer 123, and the interlayer insulating layer 124. Accordingly, the bending groove BDG extends to a part of the substrate 110.

Since inorganic insulating materials have relatively high stress against deformation, cracks or damage of inorganic insulating materials may easily occur due to bending stress.

However, according to an embodiment, as the circuit layer 120 includes the bending groove BDG, the inorganic insulating material may be removed in the bending area BA, so that cracks or damage due to bending stress may be prevented.

According to an embodiment, the display device 100 may further include the bank BNK covering the bending groove BDG.

The bank BNK is used to fill the bending groove BDG and protect the bending lines BDL (see FIG. 8).

The bank BNK may include two or more bank layers BNL1, BNL2, BNL3, and BNL4 stacked on each other.

Each of the two or more bank layers BNL1, BNL2, BNL3, and BNL4 may include an organic insulating material.

As an example, two or more bank layers may include the first bank layer BNL1 disposed on the same layer as the first planarization layer 125, the second bank layer BNL2 disposed on the same layer as the second planarization layer 126, the third bank layer BNL3 disposed on the same layer as the pixel defining layer 132, and the fourth bank layer BNL4 disposed on the same layer as the spacer layer 132′.

As illustrated in FIGS. 10 and 11, the bending lines BDL (see FIG. 8) may be formed of the second source-drain conductive layer SDCDL2 (see FIG. 9) and disposed on the first bank layer BNL1.

According to an embodiment, the circuit layer 120 may include a sub-buffer portion SBF covering the bending groove BDG.

The sub-buffer portion SBF may include an inorganic insulating material.

The sub-buffer portion SBF may be disposed on the same layer as the main buffer portion MBF (see FIG. 9) disposed in the main region MA (see FIG. 8) and covering the grid GRD (see FIG. 9).

The sub-buffer portion SBF may be disposed between the bank BNK and the substrate 110.

According to an embodiment illustrated in FIGS. 10 and 11, the sub-buffer portion SBF covering the bending groove BDG may be disposed together with the main buffer portion MBF (see FIG. 9) covering the grid GRD. The main buffer portion MBF and the sub-buffer portion SBF may include an inorganic insulating material.

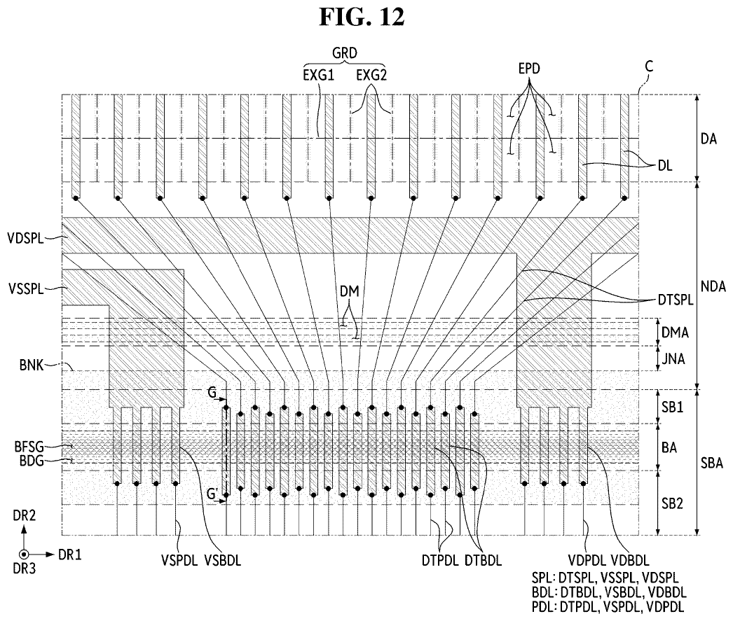

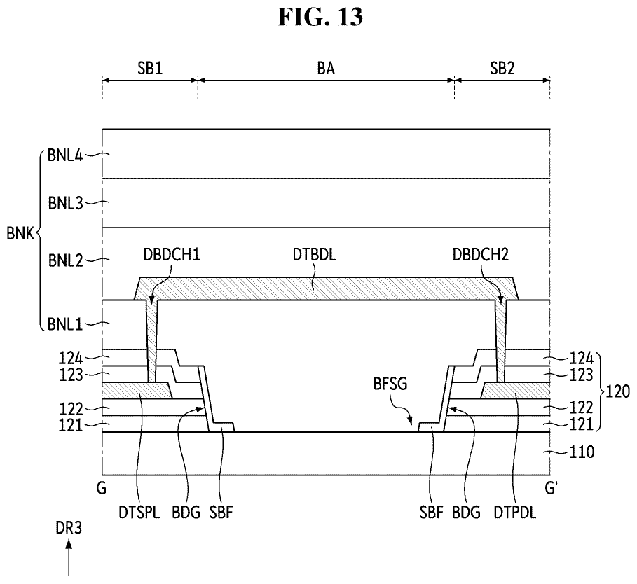

FIG. 12 is a layout showing a part C of FIG. 7 according to an embodiment. FIG. 13 is a cross-sectional view taken along a line G-G′ of FIG. 12.

The display device 100 illustrated in FIGS. 12 and 13 is substantially the same as the display device 100 illustrated in FIGS. 1 to 11 except that a buffer separation groove BFSG extending through the sub-buffer portion SBF is further formed in the bending area BA, and redundant description will be omitted below.

As illustrated in FIG. 12, the buffer separation groove BFSG may extend in the first direction DR1 crossing the second direction DR2 along which the first sub-region SB1 and the second sub-region SB2 face each other.

As illustrated in FIG. 13, the sub-buffer portion SBF may be removed by the buffer separation groove BFSG.

As an example, a portion of the sub-buffer portion SBF that is in contact with the substrate 110 may be removed by the buffer separation groove BFSG.

Accordingly, the portion of the sub-buffer portion SBF adjacent to the first sub-region SB1 may be spaced apart from another portion of the sub-buffer portion SBF adjacent to the second sub-region SB2 by the buffer separation groove BFSG.

Additionally, the bank BNK may be in contact with the substrate 110 through the bending groove BDG and the buffer separation groove BFSG.

According to an embodiment, as the sub-buffer portion SBF may be removed by the buffer separation groove BFSG, cracks or damage of the sub-buffer portion SBF due to bending stress may be prevented, even when the bending area BA is transformed into a bent shape.

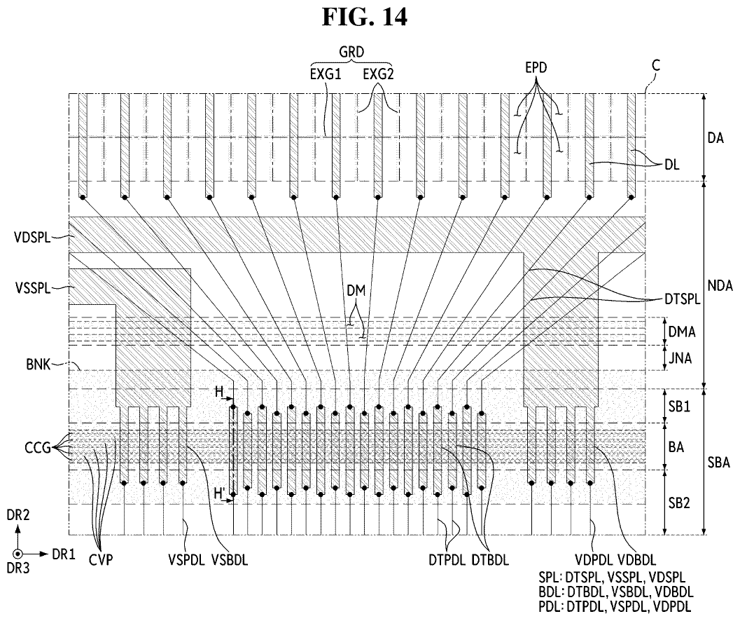

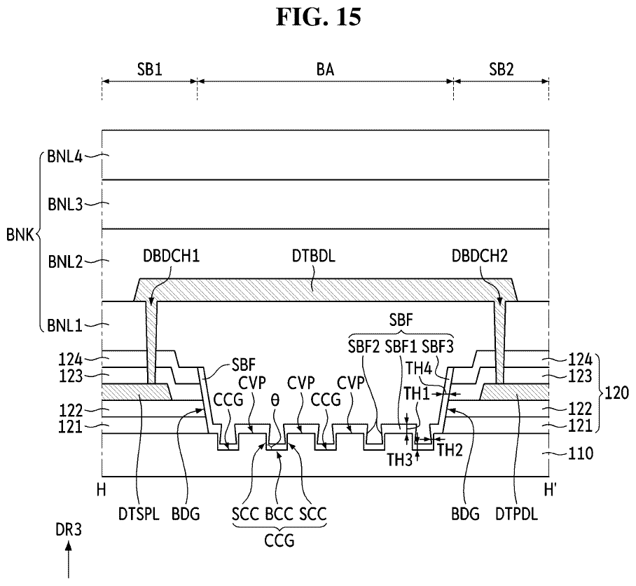

FIG. 14 is a layout showing a part C of FIG. 7 according to an embodiment. FIGS. 15, 16, and 17 are cross-sectional views taken along a line H-H′ of FIG. 14 according to an embodiment.

The display device 100 illustrated in FIG. 14 is substantially the same as the display device illustrated in FIGS. 1 to 11 except that two or more concave grooves CCG formed in the bending area BA, and one or more convex portions CVP disposed between two or more concave grooves CCG are further included. Thus, redundant description will be omitted below.

As illustrated in FIG. 14, each of the two or more concave grooves CCG may extend in the first direction DR1 crossing the second direction DR2 along which the first sub-region SB1 and the second sub-region SB2 face each other.

Two or more concave grooves CCG may be arranged in the second direction DR2 along which the first sub-region SB1 and the second sub-region SB2 face each other.

That is, two or more concave grooves CCG and one or more convex portions CVP may be arranged alternately in the second direction DR2 in which the first sub-region SB1 and the second sub-region SB2 face each other.

As illustrated in FIG. 15, each of the two or more concave grooves CCG may extend through a part of the substrate 110.

That is, the depth of each of the two or more concave grooves CCG may be less than a thickness of the substrate 110.

Each of the two or more concave grooves CCG may include a bottom surface BCC and a side surface SCC connecting the bottom surface BCC of the concave grooves CCG to the convex portion CVP or the surface of the substrate 110.

According to an embodiment of FIG. 15, an inclination θ of the side surface SCC with respect to the bottom surface BCC in each of the two or more concave grooves CCG may be 90 degrees or less.

According to an embodiment illustrated in FIG. 15, a portion of the substrate 110 overlapping or being exposed by the bending groove BDG may have a surface with a concavo-convex structure formed by two or more concave grooves CCG and one or more convex portions CVP disposed therebetween.

The sub-buffer portion SBF may cover a portion of the substrate 110 exposed through the bending groove BDG and having a surface with a concavo-convex structure.

By adjusting the deposition direction during the deposition process of an inorganic insulating material for placing the main buffer portion MBF (see FIG. 9) and the sub-buffer portion SBF, the sub-buffer portion SBF that covers a portion of the substrate 110 having a surface with a concavo-convex structure may be partially deposited with a thin layer.

That is, the sub-buffer portion SBF may include a first thickness portion SBF1 disposed on one or more convex portions CVP with a first thickness TH1, and a second thickness portion SBF2 disposed on a side surface of each of the two or more concave grooves CCG with a second thickness TH2 which is less than or equal to the first thickness TH1.

In addition, the sub-buffer portion SBF may further include a third thickness portion SBF3 disposed on the bottom surface of each of the two or more concave grooves CCG with a third thickness TH3 that is greater than or equal to the second thickness TH2 and less than or equal to the first thickness TH1.

Since the second thickness portion SBF2 of the sub-buffer portion SBF has a relatively thin thickness, which is less than or equal to the second thickness TH2, the second thickness portion SBF2 may be easily broken.

Accordingly, although a separate mask process and an etching process are not performed to partially remove the sub-buffer portion SBF after its deposition, the sub-buffer portion may be partially removed or separated by the side surface of two or more concave grooves CCG. As a result, cracks or damage in the sub-buffer portion SBF may be relatively easily prevented from being transmitted to the display area DA.

According to an embodiment illustrated in FIG. 15, the inclination θ of the side surface SCC with respect to the bottom surface BCC in each of the two or more concave grooves CCG may be about 90 degrees.

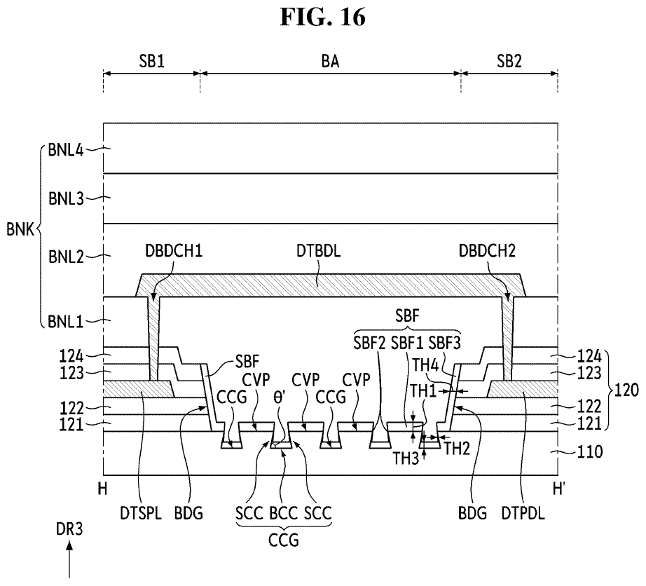

However, as illustrated in FIG. 16, according to an embodiment, an inclination θ′ of the side surface SCC with respect to the bottom surface BCC in each of the two or more concave grooves CCG may be less than 90 degrees.

That is, the cross section of each of the two or more concave grooves CCG may have a trapezoidal shape.

In this way, since the edge of one or more convex portions CVP may protrude beyond the side surface of each of the concave grooves CCG, it may be difficult for the inorganic insulating material of the sub-buffer portion SBF to be disposed on the side surface of two or more concave grooves CCG during the deposition process of an inorganic insulating material. Accordingly, since the second thickness portion SBF2 may be disposed with a thinner thickness or be removed, the sub-buffer portion SBF may be separated by two or more concave grooves CCG.

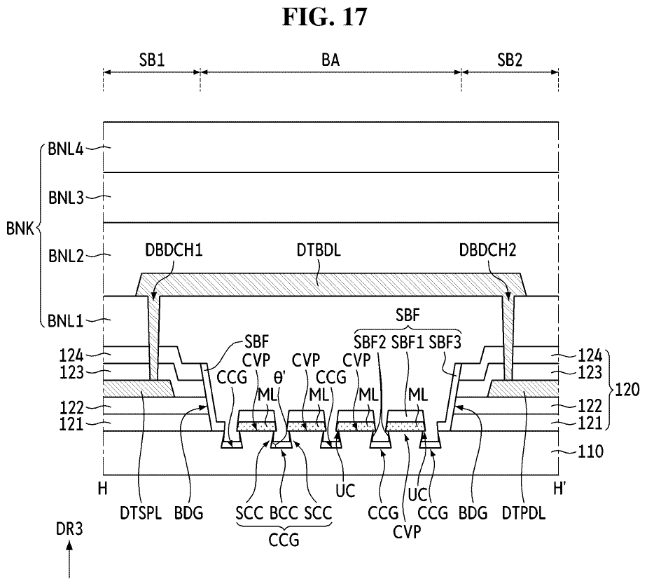

The display device 100 illustrated in FIG. 17 is substantially the same as the display device illustrated in FIG. 15 or FIG. 16 except that one or more mask layers ML disposed on one or more convex portions CVP are further included and the sub-buffer portion SBF covers one or more mask layers ML. Thus, redundant description will be omitted below.

According to an embodiment of FIG. 17, one or more mask layers ML may include a metal material.

As an example, one or more mask layers ML may be disposed on the same layer as the light blocking layer LB (see FIG. 9) which is disposed on the substrate 110.

One or more mask layers ML may be relatively hard masks and may protect one or more convex portions CVP from etching materials during an etching process for arranging two or more concave grooves CCG. Accordingly, it may be easier for an inclination θ″ of the side surface of two or more concave grooves CCG to be less than 90 degrees.

Additionally, as one or more mask layers ML includes a material having a smaller etching rate compared to the substrate 110, a width of one or more mask layers ML may be greater than a width of one or more convex portions CVP.

That is, the edges of one or more mask layers ML may protrude beyond two or more concave grooves CCG.

As a result, an undercut structure UC may be provided between the mask layer ML and the concave groove CCG.

In this way, the undercut structure UC makes it difficult for an inorganic insulating material to be deposited on a portion of the side surface of each of the concave grooves CCG that overlaps the mask layer ML. Accordingly, the second thickness portion SBF2 may be separated from the first thickness portion SBF1. That is, the sub-buffer portion SBF may be more clearly separated by one or more mask layers ML and two or more concave grooves CCG.

Accordingly, the reliability of crack blocking of the sub-buffer portion SBF may be improved.

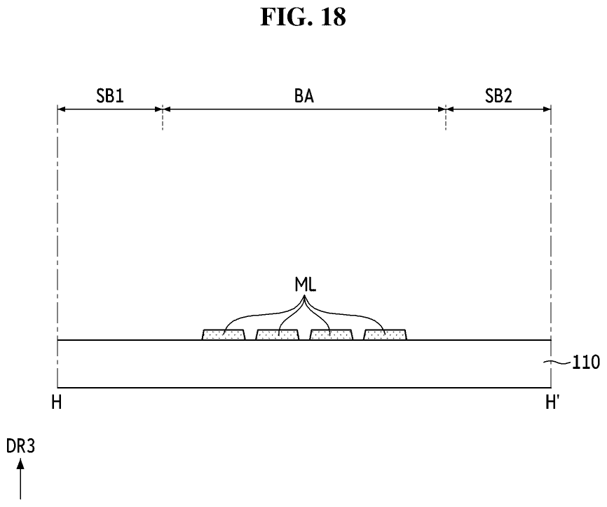

FIGS. 18, 19, 20, 21, and 22 are process diagrams illustrating steps in the method of manufacturing a display device according to an embodiment of FIG. 17.

As illustrated in FIG. 18, one or more mask layers ML may be disposed on the bending area BA by partially removing the metal material on the substrate 110.

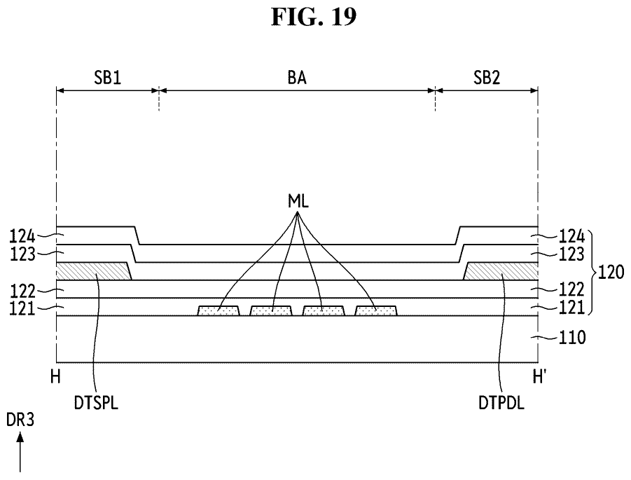

As illustrated in FIG. 19, by performing the process of depositing the inorganic insulating materials multiple times, the substrate buffer layer 121 covering one or more mask layers ML may be disposed on the substrate 110, the first gate insulating layer 122 may be disposed on the substrate buffer layer 121, the second gate insulating layer 123 may be disposed on the first gate insulating layer 122, and the interlayer insulating layer 124 may be disposed on the second gate insulating layer 123.

The first gate insulating layer 122 may cover the first gate conductive layer GCDL1 (see FIG. 9).

The second gate insulating layer 123 may cover the second gate conductive layer GCDL2 (see FIG. 9) (including DTSPL and DTPDL).

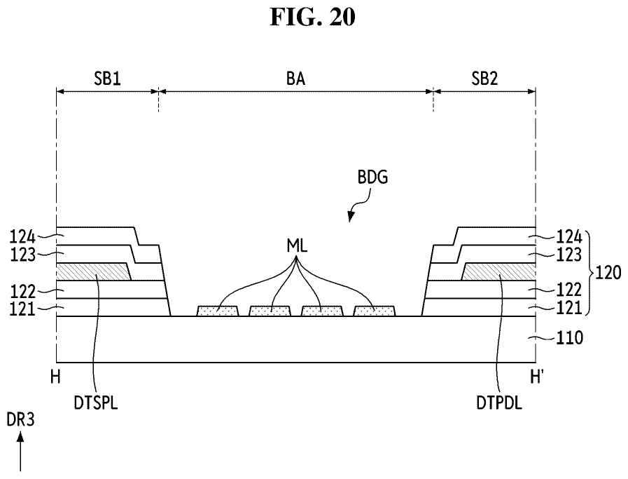

As illustrated in FIG. 20, the bending groove BDG may be formed in the bending area BA by partially removing the interlayer insulating layer 124, the second gate insulating layer 123, the first gate insulating layer 122, and the substrate buffer layer 121.

A part of the substrate 110 and one or more mask layers ML disposed thereon may be exposed through the bending groove BDG.

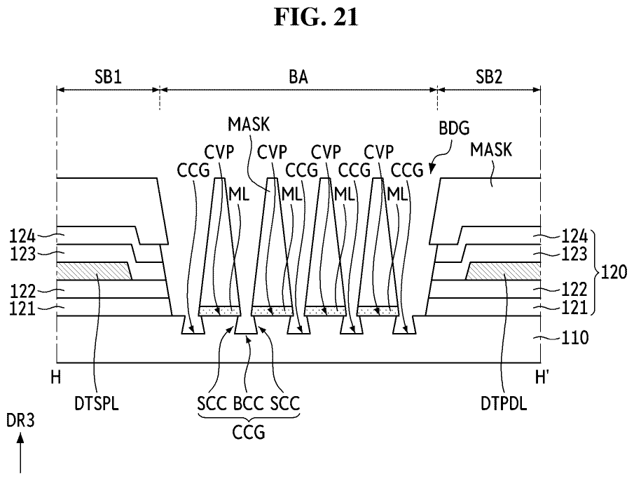

As illustrated in FIG. 21, two or more concave grooves CCG may be formed by partially removing the substrate 110 using an etching mask that covers the periphery of the bending groove BDG and one or more mask layers ML.

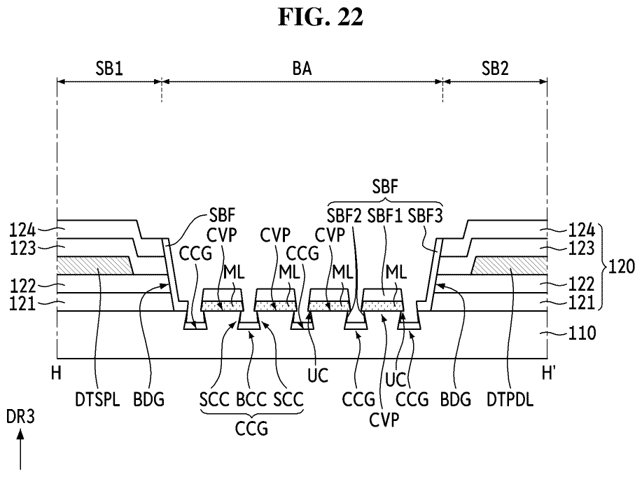

As illustrated in FIG. 22, an inorganic insulating material is deposited to form the sub-buffer portion SBF covering the bending groove BDG and one or more mask layers ML.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising a main region and a sub-region protruding from one side of the main region;
a circuit layer disposed on the substrate; and
an element layer disposed on the circuit layer,
wherein the sub-region comprises a bending area which is transformed into a bent shape, and
wherein the circuit layer comprises:
a light blocking layer disposed on the substrate;
a substrate buffer layer covering the light blocking layer;
a semiconductor layer disposed on the substrate buffer layer;
a first gate insulating layer covering the semiconductor layer;
a first gate conductive layer disposed on the first gate insulating layer;
a second gate insulating layer covering the first gate conductive layer;
a second gate conductive layer disposed on the second gate insulating layer;
an interlayer insulating layer covering the second gate conductive layer;
a grid formed in at least a part of the main region and comprising first and second extension grooves which intersect each other;
a bending groove formed in the bending area and extending through at least one of the substrate buffer layer, the first gate insulating layer, the second gate insulating layer, or the interlayer insulating layer;
a main buffer portion disposed in the main region and covering the grid; and
a sub-buffer portion covering the bending groove and disposed in the sub-region, the sub-buffer portion being disposed on a same layer as the main buffer portion,
wherein each of the first extension grooves and the second extension grooves reaches a part of at least one of the substrate, the light blocking layer, the first gate conductive layer, or the second gate conductive layer, and
wherein each of the substrate buffer layer, the first gate insulating layer, the second gate insulating layer, the interlayer insulating layer, the main buffer portion, and the sub-buffer portion contains an inorganic insulating material.

2. The display device of claim 1, wherein the main region comprises a display area in which emission areas are arranged, and a non-display area disposed around the display area,
the sub-region further comprises a first sub-region disposed between the main region and a first side of the bending area, and a second sub-region connected to a second side of the bending area, and
the grid is formed in at least the display area of the main region.

3. The display device of claim 2, wherein the circuit layer further comprises a grid filling layer disposed on the main buffer portion, filling the grid, and containing an organic insulating material.

4. The display device of claim 2, wherein the circuit layer further comprises a buffer separation groove formed in the bending area and extending through the sub-buffer portion,
the buffer separation groove extends in a first direction crossing a second direction along which the first sub-region and the second sub-region face each other, and
a portion of the sub-buffer portion adjacent to the first sub-region is spaced apart from another portion of the sub-buffer portion adjacent to the second sub-region by the buffer separation groove.

5. The display device of claim 2, further comprising:
two or more concave grooves formed in the bending area; and
one or more convex portions disposed between the two or more concave grooves,
wherein each of the two or more concave grooves extends through a part of the substrate and extends in a first direction crossing a second direction along which the first sub-region and the second sub-region face each other,
the two or more concave grooves and the one or more convex portions are arranged alternately along the second direction,
a portion of the substrate overlapping the bending groove has a surface with a concavo-convex structure formed by the two or more concave grooves and the one or more convex portions, and
the sub-buffer portion covers the portion of the substrate having the surface with the concavo-convex structure.

6. The display device of claim 5, wherein a depth of each of the two or more concave grooves is less than a thickness of the substrate.

7. The display device of claim 5, wherein a thickness of a first portion of the sub-buffer portion disposed on the one or more convex portions is a first thickness, and
a thickness of a second portion of the sub-buffer portion disposed on a side surface of each of the two or more concave grooves is a second thickness less than or equal to the first thickness.

8. The display device of claim 7, wherein an inclination of the side surface of each of the two or more concave grooves with respect to a bottom surface of each of the two or more concave grooves is less than or equal to 90 degrees.

9. The display device of claim 7, further comprising one or more mask layers disposed on the one or more convex portions,
wherein the sub-buffer portion covers the one or more mask layers.

10. The display device of claim 9, wherein an inclination of the side surface of each of the two or more concave grooves with respect to the bottom surface of each of the two or more concave grooves is less than 90 degrees.

11. The display device of claim 9, wherein a width of the one or more mask layers is greater than a width of the one or more convex portions, and
an edge of the one or more mask layers protrudes beyond the two or more concave grooves.

12. The display device of claim 9, wherein the one or more mask layers are disposed on a same layer as the light blocking layer.

13. The display device of claim 2, further comprising a bank covering the bending groove and comprising two or more bank layers stacked on each other,
wherein each of the two or more bank layers contains an organic insulating material, and
the bank is in contact with the sub-buffer portion or the substrate.

14. The display device of claim 13, wherein the circuit layer further comprises:
a first source-drain conductive layer disposed on the interlayer insulating layer;
a first planarization layer covering the first source-drain conductive layer and the grid;
a second source-drain conductive layer disposed on the first planarization layer; and
a second planarization layer covering the second source-drain conductive layer,
wherein the element layer comprises:
anode electrodes disposed in the emission areas;
a pixel defining layer disposed in a non-emission area between the emission areas and covering an edge of each of the anode electrodes;
a spacer layer disposed on a part of the pixel defining layer;
light emitting layers disposed on the anode electrodes; and
a cathode electrode disposed on the pixel defining layer, the spacer layer, and the light emitting layers, and
wherein the two or more bank layers comprise:
a first bank layer disposed on a same layer as the first planarization layer;
a second bank layer disposed on a same layer as the second planarization layer;
a third bank layer disposed on a same layer as the pixel defining layer; and
a fourth bank layer disposed on a same layer as the spacer layer.

15. A display device comprising:
a substrate comprising a main region and a sub-region protruding from one side of the main region;
a circuit layer disposed on the substrate; and
an element layer disposed on the circuit layer,
wherein the sub-region comprises a bending area which is transformed into a bent shape, a first sub-region disposed between the main region and a first side of the bending area, and a second sub-region connected to a second side of the bending area, and
the circuit layer comprises:
a light blocking layer disposed on the substrate;
a substrate buffer layer covering the light blocking layer;
a semiconductor layer disposed on the substrate buffer layer;
a first gate insulating layer covering the semiconductor layer;
a first gate conductive layer disposed on the first gate insulating layer;
a second gate insulating layer covering the first gate conductive layer;
a second gate conductive layer disposed on the second gate insulating layer;
an interlayer insulating layer covering the second gate conductive layer;
a bending groove formed in the bending area and extending through at least one of the substrate buffer layer, the first gate insulating layer, the second gate insulating layer, or the interlayer insulating layer; and
a sub-buffer portion covering the bending groove,
wherein the display device further comprising:
two or more concave grooves formed in the bending area; and
one or more convex portions disposed between the two or more concave grooves.

16. The display device of claim 15, wherein the main region comprises a display area in which emission areas are arranged, and a non-display area disposed around the display area, and
wherein the circuit layer further comprises:
a grid formed in at least the display area of the main region and comprising first and second extension grooves which intersect each other; and
a main buffer portion disposed in the main region and covering the grid, the main buffer portion being disposed on a same layer as the sub-buffer portion,
wherein each of the first extension grooves and the second extension grooves reaches a part of at least one of the substrate, the light blocking layer, the first gate conductive layer, or the second gate conductive layer, and
each of the substrate buffer layer, the first gate insulating layer, the second gate insulating layer, the interlayer insulating layer, the sub-buffer portion, and the main buffer portion contains an inorganic insulating material.

17. The display device of claim 16, wherein each of the two or more concave grooves extends through a part of the substrate and extends in a first direction crossing a second direction along which the first sub-region and the second sub-region face each other,
the two or more concave grooves are arranged along the second direction,
a portion of the substrate overlapping the bending groove has a surface with a concavo-convex structure formed by the two or more concave grooves and the one or more convex portions,
the sub-buffer portion covers the portion of the substrate having the surface with the concavo-convex structure, and
a depth of each of the two or more concave grooves is less than a thickness of the substrate.

18. The display device of claim 17, wherein a thickness of a first portion of the sub-buffer portion disposed on the one or more convex portions is a first thickness, and
a thickness of a second portion of the sub-buffer portion disposed on a side surface of each of the two or more concave grooves is a second thickness less than or equal to the first thickness.

19. The display device of claim 17, further comprising one or more mask layers disposed on the one or more convex portions,
wherein an inclination of the side surface of each of the two or more concave grooves with respect to a bottom surface of the two or more concave grooves is less than or equal to 90 degrees, and
the sub-buffer portion covers the one or more mask layers.

20. The display device of claim 19, wherein a width of the one or more mask layers is greater than a width of the one or more convex portions, and
an edge of the one or more mask layers protrudes beyond the two or more concave grooves.
